(19) United States
(12) Patent Application Publication
(10) Pub. No.: US 2018/0006178 A1
(43) Pub. Date: Jan. 4, 2018

(54) SOLAR CELL MODULE

(71) Applicant: PANASONIC INTELLECTUAL PROPERTY MANAGEMENT CO., LTD., Osaka (JP)

(72) Inventors: Saori NAGASHIMA, Osaka (JP); Yoshihide KAWASHITA, Osaka (JP)

(73) Assignee: PANASONIC INTELLECTUAL PROPERTY MANAGEMENT CO., LTD., Osaka (JP)

(21) Appl. No.: 15/702,346

(22) Filed: Sep. 12, 2017

Related U.S. Application Data
(63) Continuation of application No. PCT/JP2016/000658, filed on Feb. 9, 2016.

(30) Foreign Application Priority Data
Mar. 30, 2015 (JP) 2015-067869

(51) Int. Cl. H01L 31/048; H01L 31/049

(52) U.S. Cl. CPC H01L 31/0481; H01L 31/049; H01L 31/0488

(57) ABSTRACT

A solar cell module includes a solar cell string, a first encapsulant, a second encapsulant having a viscoelasticity greater than a viscoelasticity of the first encapsulant, a front-side protective plate, and a back-side protective sheet. The solar cell string includes a plurality of solar cells and a line member which electrically connects the plurality of solar cells. The lengthwise direction of the line member is different from the maximum expansion and contraction direction of the back-side protective sheet.

### CROSS REFERENCE TO RELATED APPLICATIONS

This application is a U.S. continuation application of PCT International Patent Application Number PCT/JP2016/000658 filed on Feb. 9, 2016, claiming the benefit of priority of Japanese Patent Application Number 2015-067869 filed on Mar. 30, 2015, the entire contents of which are hereby incorporated by reference.

### BACKGROUND

### 1. Technical Field

The present disclosure relates to a solar cell module.

### 2. Description of the Related Art

Solar cells show promise as new energy sources as they can directly convert clean and inexhaustibly supplied solar energy into electric energy.

In general, the output per solar cell is approximately several watts. Accordingly, when using such a solar cell as a power source for a house, a building or the like, a solar cell module is used which provides higher output power by including a plurality of solar cells electrically connected to each other. A solar cell module has, for example, a configuration as described below.

First, a solar cell string is prepared which includes a plurality of solar cells electrically connected in series using conductive line members. The solar cell string is sealed by a resin such as ethylene vinyl acetate (EVA) copolymer. A glass or composite resin sheet for shock protection serving as a protective member is provided over the resin.

For the protective member on the light entering side, a tempered glass is often used to protect the solar cell module from an object falling onto the surface of the solar cell module. In contrast, for a protective member on the back side of the solar cell module which often mainly faces the roof material, a thin soft composite resin sheet is often used.

In recent years, an example of an encapsulant for sealing a solar cell string has been presented where resin sheets made of different materials are combined to increase the weather resistance of the solar cell module (for example, see Japanese Unexamined Patent Application Publication No. 2011-159711).

### SUMMARY

The present disclosure provides a solar cell module with increased weather resistance.

According to an aspect of the present disclosure, a solar cell module A solar cell module includes: a front-side protective plate disposed on a light entering side; a first encapsulant; a solar cell string; a second encapsulant; and a back-side protective sheet. In the front-side protective plate, the first encapsulant, the solar cell string, the second encapsulant, and the back-side protective sheet are layered in a stated order. The solar cell string includes a plurality of solar cells and a line member which electrically connects the plurality of solar cells. The first encapsulant has a viscoelasticity less than a viscoelasticity of the second encapsulant, and a lengthwise direction of the line member is different from a maximum expansion and contraction direction of the back-side protective sheet.

According to the present disclosure, it is possible to provide a solar cell module with increased weather resistance.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a partial plan view of the front side of a solar cell module according to an embodiment;

FIG. 2 is a cross-sectional view of the solar cell module taken along line A-A in FIG. 1;

FIG. 3 is an overhead view of a state of a back-side protective sheet before being processed;

FIG. 4 is an enlarged view of the dashed-line region in FIG. 2; and

FIG. 5 illustrates an exploded layout of respective components included in the solar cell module according to the embodiment.

### DETAILED DESCRIPTION OF THE EMBODIMENT

An embodiment according to the present disclosure will be described with reference to the drawings. In the drawings, the same or similar parts are denoted by the same or similar reference numerals. The drawings, however, are merely schematic in nature, and may not reflect actual dimensional proportions, etc. Therefore, specific dimensions and the like should be determined in light of the following description. Moreover, dimensional relations and proportions may of course vary from one drawing to another.

### Configuration of Solar Cell Module

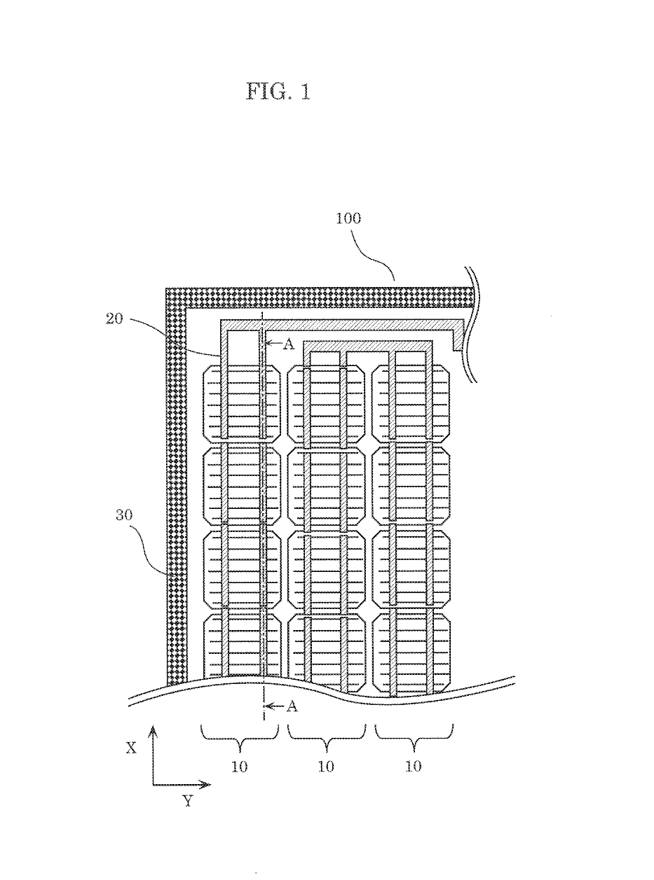

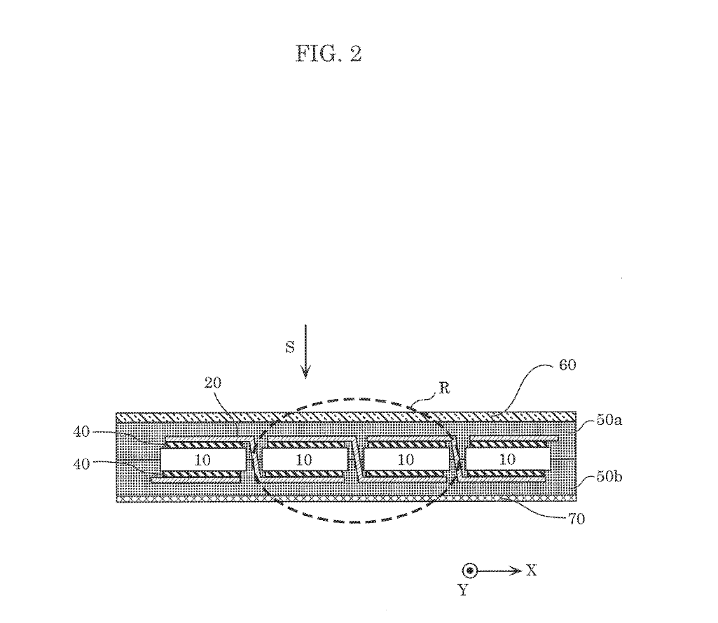

A schematic configuration of solar cell module 100 according to the present embodiment will be described with reference to FIG. 1 and FIG. 2.

FIG. 1 is a partial plan view of the front side of solar cell module 100 according to the embodiment. FIG. 2 is a cross-sectional view of solar cell module 100 taken along line A-A in FIG. 1. As illustrated in FIG. 1, solar cell module 100 includes solar cell strings each including a plurality of solar cells 10 electrically connected to each other with line members 20. Solar cell module 100 includes frame 30 made of a metal such as aluminum along the periphery of solar cell module 100. Referring to the coordinates in FIG. 1, each solar cell string extends in the x-axis direction.

As illustrated in FIG. 2, in each of the solar cell strings, a minimum unit of two solar cells 10 are connected in series with one line member 20, and a plurality of the minimum units are connected. Thus, line members 20 for connecting solar cells 10 extend in the x-axis direction in the same manner as the solar cell strings.

Adjacent two solar cells, which are a first solar cell and a second solar cell, each include a first main surface and a second main surface. The first main surface has a polarity different from the polarity of the second main surface. In order to electrically connect such two solar cells 10 in series, the first main surface of first solar cell 10 is electrically connected to the second main surface of second solar cell 10 with line member 20. Here, solar cells 10 and line members 20 are electrically connected via grid electrodes 40 formed on both surfaces of solar cells 10. In other words, line members 20 are not flat in cross-section, but are bent as illustrated in FIG. 2.

Line members 20 may have uneven surfaces. This allows sunlight entering the surfaces of line members 20 to scatter and re-enter the surfaces of the solar cells. Accordingly, it is possible to reduce the light shielding loss caused due to the alignment of line members 20.

Solar cell strings are protected from both front and back sides by encapsulants 50a and 50b made of resin sheets. Solar cell module 100 includes front-side protective plate 60 which further protects encapsulant 50a, and back-side protective sheet 70 which further protects encapsulant 50b. Arrow S in FIG. 2 indicates the direction of sunlight mainly entering solar cell module 100 when solar cell module 100 is installed outdoors.

Materials of encapsulants 50a and 50b may be selected from among the group consisting of thermoplastic resin and thermosetting resin including polyolefins, polyethylenes, polyphenylenes and copolymers thereof. Encapsulants 50a and 50b are cured by thermal press fitting. At high temperatures, the viscoelasticity of encapsulant 50a on the front side is less than the viscoelasticity of encapsulant 50b on the back side. In the present embodiment, as an example, a polyolefin resin is used for encapsulant 50a and ethylene-vinyl acetate copolymer (EVA) is used for encapsulant 50b.

For front-side protective plate 60 which further protects solar cell module 100 from above encapsulant 50a, a material which has a high optical transparency and has hardness to the extent that it can protect the surface of solar cell module 100 from a falling object or the like. Examples of such a material include a glass plate and an acrylic resin plate. Moreover, such a material may be harder than cured encapsulant 50a. In the present embodiment, a tempered glass plate is used.

For back-side protective sheet 70 which further protects solar cell module 100 from above encapsulant 50b, a hard glass material having a high weather resistance, a resin sheet having a high flexibility, a high heat resistance and a high water resistance, or a high-weather resistant composite resin sheet including a stack of a plurality of materials is generally used. In particular, in light of product weight and manufacturing cost, a composite resin sheet is often used. In the present embodiment, a composite resin sheet mainly including polyethylene terephthalate is used.

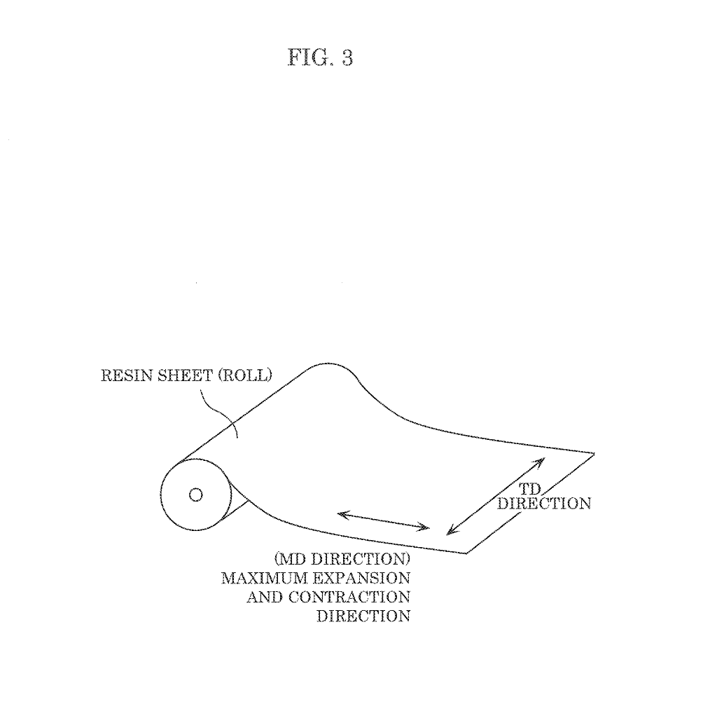

FIG. 3 is an overhead view of a state of back-side protective sheet 70 before being processed. A composite resin sheet is wound into a single roll while being strongly pulled at the final stage in the manufacturing process. Subsequently, the resin sheet is processed into a desired size by, for example, cutting or punching. Here, the direction in which the resin sheet is wound is referred to as machine direction (MD), and the direction perpendicular to the MD is referred to as transverse direction (TD).

The resin sheet thus manufactured inherently has expansion and contraction stress in the MD direction. When such a resin sheet expands or contracts due to heat cycles, the expansion and contraction rate in the MD direction is greater than the expansion and contraction rate in the TD direction. Therefore, in the following description, the MD direction is defined as a “maximum expansion and contraction direction” of the resin sheet. The winding direction of the resin sheet can also be measured by checking the orientation of the molecules in the resin using chemical analysis techniques.

When a composite resin sheet is used for back-side protective sheet 70 of solar cell module 100, back-side protective sheet 70 deforms, expands, or contracts due to, for example, the temperature cycle at the time of use of solar cell module 100. The inventors of the present application have found that in a case where a solar cell string is sealed by a combination of resin sheets made of different materials, the solar cells in the solar cell string may move under certain conditions due to the heat cycle at the time of use of solar cell module 100.

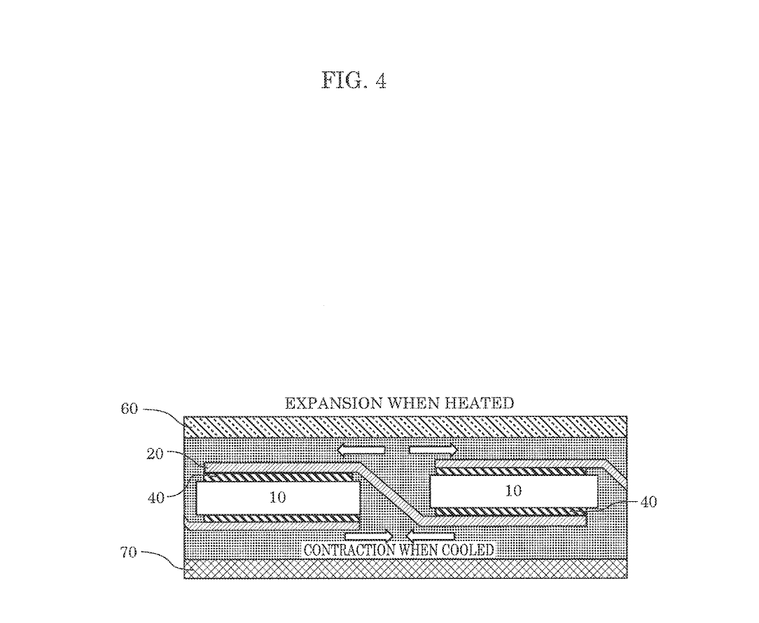

FIG. 4 is an enlarged view of dashed-line region R in FIG. 2. When solar cell module 100 is heated, the encapsulants expand, and the gap between the solar cells increases. When solar cell module 100 is cooled, the encapsulants contract, and the gap between the solar cells decreases. This change in gap between the solar cells is expected to put a load on line members 20. If line members 20 are under load over a long period of time, line members 20 may deteriorate due to metal fatigue. In other words, the present embodiment is for reducing metal fatigue of line members 20.

### Arrangement of Back-side Protective Sheet 70

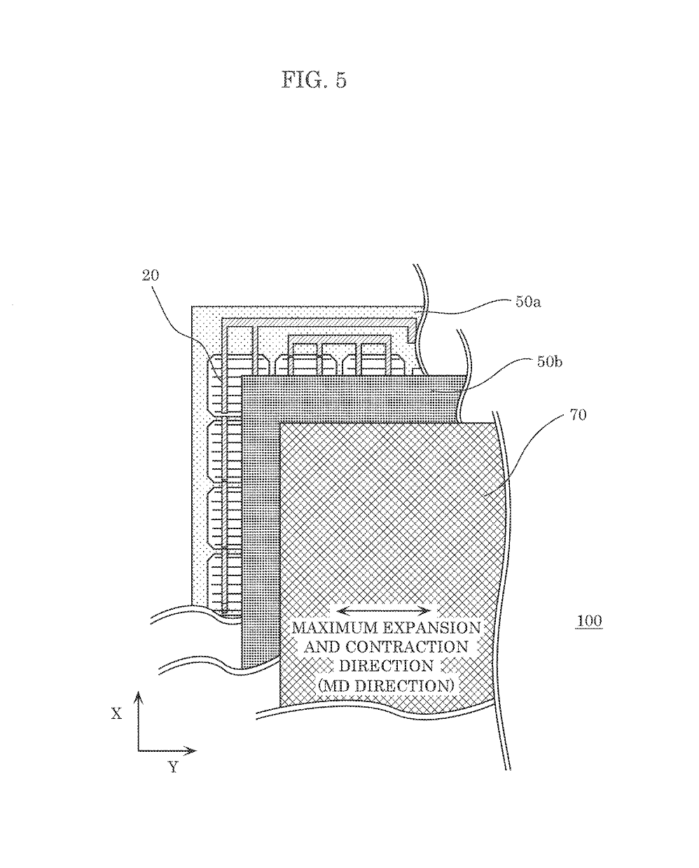

FIG. 5 illustrates an exploded layout of respective components included in solar cell module 100 according to the present embodiment. As illustrated in FIG. 5, the lengthwise direction of line members 20 is set so that it does not match the maximum expansion and contraction direction of back-side protective sheet 70. Specifically, the lengthwise direction of line members 20 is set to be the X-axis direction, and the maximum expansion and contraction direction of back-side protective sheet 70 is set to be the Y-axis direction. In other words, the lengthwise direction of line members 20 is orthogonal to the maximum expansion and contraction direction of back-side protective sheet 70.

By setting the maximum expansion and contraction direction of back-side protective sheet 70 to be orthogonal to the lengthwise direction of each line member 20, it is possible to reduce the expansion and contraction stress of back-side protective sheet 70 in the X-direction acting on line member 20. In particular, reduction in expansion and contraction stress of back-side protective sheet 70 leads to reduction in load applied to the bent portion of line member 20 in FIG. 4.

In the present embodiment, the expression that the lengthwise direction is “orthogonal” to the maximum expansion and contraction direction indicates that the range of the angle formed by the lengthwise direction and the maximum expansion and contraction direction is 90 degrees±10 degrees approximately. However, setting the lengthwise direction of line member 20 so that it does not match the maximum expansion and contraction direction of back-side protective sheet 70 can produce an effect of reducing the expansion and contraction stress in the X-direction compared to the case where the directions match. In order to provide a certain effect, the range of the angle formed by the lengthwise direction of line member 20 and the maximum expansion and contraction direction of back-side protective sheet 70 may fall within the range of 90 degrees±45 degrees.

The following describes the reasons that the load applied to the bent portion of line member 20 can be reduced by the configuration of solar cell module 100 thus described.

First, a description is given of the case where materials which are hard and have high viscoelasticity after thermal curing are used for encapsulants 50a and 50b. When solar cell module 100 is used outdoors, back-side protective sheet 70 expands or contracts due to the heat cycle, and the stress propagates to encapsulant 50b. However, since encapsulants 50a and 50b which are thermally cured and bonded to each other are both sufficiently hard, encapsulants 50a and 50b are less likely to expand or contract even upon application of the expansion and contraction stress from back-side protective sheet 70. Accordingly, in this case, the expansion and contraction stress applied to the solar cell string sealed by encapsulants 50a and 50b is small, so that the expansion and contraction stress is also less likely to be applied to the bent portion of line member 20.

On the other hand, when encapsulants 50a and 50b differ in viscoelasticity and the viscoelasticity of encapsulant 50a is less than the viscoelasticity of encapsulant 50b, the expansion and contraction stress of back-side protective sheet 70 propagated to encapsulant 50b is less likely to be blocked by encapsulant 50a. In other words, when encapsulant 50b expands or contracts due to the expansion or contraction of back-side protective sheet 70, the expansion and contraction stress is applied to the solar cell string bonded to encapsulant 50b. Here, the solar cells in the solar cell string are movable when encapsulant 50a has fluidity. Hence, the gap between the solar cells changes, and a load is expected to be applied to the bent portion of line member 20.

In view of the above reason, when encapsulants 50a and 50b differ in viscoelasticity and the viscoelasticity of encapsulant 50a is less than the viscoelasticity of 50b, the stress applied by the expansion or contraction of back-side protective sheet 70 to the bent portion of line member 20 can be reduced by setting the maximum expansion and contraction direction of back-side protective sheet 70 to be different from the lengthwise direction of line member 20 compared to the case where the directions match. Accordingly, less load is applied to the bent portion of line member 20, leading to increased reliability of solar cell module 10 compared to a conventional one.

In the present embodiment, a method for connecting line member 20 to solar cell 10 is not particularly limited. Specifically, line member 20 may be connected to solar cell 10 by soldering using a copper line member which is a solder-coated copper core. It may also be that a solder-coated copper line member or a non-solder-coated copper line member, for example, is prepared and line member 20 is connected to solar cell 10 using a resin adhesive.

Moreover, any line member used in a general solar cell module may be used for line member 20.

Moreover, grid electrode 40 may be made of a metal other than silver. Specifically, grid electrode 40 mainly made of copper may be formed through electrolytic plating or the like.

The present embodiment has described the relationship between the lengthwise direction of line member 20 and the maximum expansion and contraction direction of back-side protective sheet 70. However, encapsulants 50a and 50b for sealing the solar cell string are also resin sheets which are manufactured through the similar process as back-side protective sheet 70 and which inherently have expansion and contraction stress in the MD direction. Therefore, it is understandable that the similar advantageous effects can be provided with respect to the relationship between the maximum expansion and contraction direction of encapsulants 50a and 50b and the lengthwise direction of line member 20. In other words, the similar advantageous effects to the present embodiment can be obtained by setting the maximum expansion and contraction direction of encapsulants 50a and 50b so as not to match the lengthwise direction of line member 20. Here, with respect to the angle at which the encapsulants are arranged, in the similar manner to the case where the back-side protective sheet is arranged, the angle formed by the maximum expansion and contraction direction of encapsulants 50a and 50b and the lengthwise direction of line member 20 may fall within a range of 90 degrees±45 degrees, more preferably, the range of 90 degrees±10 degrees.

In a plan view of the solar cells (XY plane), solar cell module 100 according to the present embodiment has a rectangular outer shape having long sides and short sides. The direction of the long sides may match the lengthwise direction of line member 20. When the lengthwise direction of line member 20 matches the long sides of solar cell module 100, the expansion and contraction stress due to heat history increases. However, even in this case, too, by setting the lengthwise direction of line member 20 to be different from the maximum expansion and contraction direction of back-side protective sheet 70, less load is applied to the bent portion of line member 20, leading to increased reliability of solar cell module 100 compared to a conventional one.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a front-side protective plate disposed on a light entering side;
a first encapsulant;
a solar cell string;
a second encapsulant; and
a back-side protective sheet,
wherein the front-side protective plate, the first encapsulant, the solar cell string, the second encapsulant, and the back-side protective sheet are layered in a stated order,
the solar cell string includes a plurality of solar cells and a line member which electrically connects the plurality of solar cells,
the first encapsulant has a viscoelasticity less than a viscoelasticity of the second encapsulant, and
a lengthwise direction of the line member is different from a maximum expansion and contraction direction of the back-side protective sheet.

2. The solar cell module according to claim 1,
wherein an alignment direction of the plurality of solar cells is orthogonal to the maximum expansion and contraction direction of the back-side protective sheet.

3. The solar cell module according to claim 1,
wherein the line member has an uneven surface.

4. The solar cell module according to claim 1,
wherein the solar cell module has a rectangular shape having a long side and a short side, in a plan view of the plurality of solar cells, and
a direction of the long side is identical to the lengthwise direction of the line member.
